(19) United States
(12) Patent Application Publication
(10) Pub. No.: US 2025/0149225 A1
(43) Pub. Date: May 8, 2025

(54) INDUCTOR AND METHOD OF PRODUCING THE INDUCTOR

(71) Applicant: NITTO DENKO CORPORATION, Osaka (JP)

(72) Inventors: Yoshihiro FURUKAWA, Osaka (JP); Keisuke OKUMURA, Osaka (JP)

(73) Assignee: NITTO DENKO CORPORATION, Osaka (JP)

(21) Appl. No.: 18/837,113

(22) PCT Filed: Feb. 14, 2023
(86) PCT No.: PCT/JP2023/004978

§ 371 Date: Aug. 8, 2024

(30) Foreign Application Priority Data
Feb. 16, 2022 (JP) 2022-022186

(51) Int. Cl. H01F 17/06; H01F 41/061

(52) U.S. Cl. CPC H01F 17/06; H01F 41/061

(57) ABSTRACT

An inductor includes a magnetic sheet and a conductive portion. The magnetic sheet has a penetration hole. The penetration hole is along a thickness direction. The penetration hole is open toward one side and the other side in the thickness direction. The magnetic sheet contains a cured resin and magnetic particles. The conductive portion is filled in the penetration hole. The conductive portion is along the thickness direction of the magnetic sheet.

### TECHNICAL FIELD

The present invention relates to an inductor and a method of producing the inductor.

### BACKGROUND ART

There has been a known inductor including a board having a penetration hole, a conductive portion disposed inside the penetration hole, a magnetic layer disposed between the inner side surface of the penetration hole and the outer side surface of the conductive portion (for example, see Patent Document 1 below).

### CITATION LIST

### Patent Document

Patent Document 1: Japanese Unexamined Patent Publication No. 2015-135870

### SUMMARY OF THE INVENTION

### Problem to be Solved by the Invention

The inductor is required to have a high inductance and sufficient superimposed DC current characteristics. However, in the inductor described in Patent Document 1, the magnetic material is formed only on a side surface of the conductive portion. There are limits on the inductor to satisfy the high inductance and sufficient superimposed DC current characteristics.

Furthermore, the method of producing the inductor is required to easily form the conductive portion while increasing the degree of freedom of the disposition of the conductive portion.

The present invention provides an inductor having a high inductance and sufficient superimposed DC current characteristics, and a method of producing an inductor that can produce an inductor having a high inductance and sufficient superimposed DC current characteristics, and can easily form the conductive portion while increasing the degree of freedom of the disposition of the conductive portion.

### Means for Solving the Problem

The present invention [1] includes a method of producing an inductor, the method including: a step of curing a curable sheet containing a curable resin and magnetic particles to form a magnetic sheet extending in a direction perpendicular to a thickness direction: a step of forming a penetration hole in the magnetic sheet so that the penetration hole is open toward one side and the other side of the magnetic sheet in the thickness direction and is along the thickness direction; and a step of forming a conductive portion in the penetration hole so that the conductive portion is along the thickness direction of the magnetic sheet.

According to the production method, the magnetic sheet extends in a plane direction perpendicular to the thickness direction. In other words, the magnetic sheet has a wide area in the plane direction. Then, the penetration hole is formed at an arbitrary position in the magnetic sheet, and thereafter the conductive portion can be formed in the penetration hole. Thus, the conductive portion can easily be formed while the degree of freedom of the disposition of the conductive portion is increased.

Furthermore, the magnetic sheet extends in the plane direction, and thus can improve the inductance and superimposed DC current characteristics of the inductor.

The present invention [2]1 includes the method of producing an inductor described in the above-described [1], wherein in the step of forming a penetration hole, the magnetic sheet is processed by at least one selected from the group consisting of drilling, blasting, and dicing.

According to the production method, in the step of forming a penetration hole, the magnetic sheet is processed by at least one selected from the group consisting of drilling, blasting, and dicing, and thus the penetration hole can easily be formed at an arbitrary position in the magnetic sheet.

The present invention [3] includes the method of producing an inductor described in the above-described [1] or [2], the method further including: a step of forming an insulating layer on an inner peripheral surface facing the penetration hole in the magnetic sheet; wherein in the step of forming a conductive portion, the conductive portion is disposed on an inner peripheral surface of the insulating layer.

According to the production method, the inductor further includes the insulating layer disposed between the inner peripheral surface of the magnetic sheet and the outer peripheral surface of the conductive portion. Thus, the conductive portion can surely be insulated from the magnetic sheet.

The present invention [4] includes the method of producing an inductor described in the above-described [3], wherein the step of forming a, conductive portion includes a step of forming an underlying layer on the inner peripheral surface of the insulating layer and on at least one surface of the magnetic sheet in the thickness direction.

According to the production method, the underlying layer is allowed to function as a connecting pad.

The present invention [5] includes the method of producing an inductor described in the above-described [4], wherein the step of forming a, conductive portion includes a step of filling a, conductive paste inside the underlying layer and calcining the conductive paste to form a main body after the step of forming the underlying layer.

According to the production method, the conductive paste is filled inside the underlying layer, and thus the main body is easily formed.

The present invention [6] includes the method of producing an inductor described in any one of the above-described [1] to [15], wherein the curable sheet contains a resin component, wherein the resin component contains: an epoxy resin and a phenol resin that are contained in the curable resin; and an acrylic resin, and wherein a content ratio of the acrylic resin in the resin component is 25 vol % or more and 60 vol % or less.

The resin component of the curable sheet contains an epoxy resin, a phenol resin, and an acrylic resin, and the content ratio of the acrylic resin in the resin component is 25 vol % or more and 60 vol % or less. Thus, when the penetration hole is formed, a high processability is imparted to the magnetic sheet.

The present invention [7]1 includes the method of producing an inductor described in the above-described [6], wherein the epoxy resin only consists of an epoxy resin having 3 or more functional groups, and wherein the phenol resin only consists of a, phenol resin having 3 or more functional groups.

The present invention [8] includes the method of producing an inductor described in the above-described [7], wherein the epoxy resin having 3 or more functional groups is a cresol novolak epoxy resin, and wherein the phenol resin having 3 or more functional groups is a phenol biphenylene resin.

The present invention [9] includes the method of producing an inductor described in the above-described [1] or [2], wherein the step of forming a penetration hole is carried out after the step of curing a curable sheet.

When a penetration hole is formed in the curable sheet before the curable sheet is thermally cured, it is difficult to control the shape in consideration of the thermal shrinkage of the curable resin, a crack appears in the curable sheet after the curable sheet is cured, or the degree of difficulty of processing the curable sheet increases.

When a penetration hole is formed in the curable sheet before the curable sheet is thermally cured, the degree of difficulty of processing the curable sheet increases. For example, it is difficult to control the shape in consideration of the thermal shrinkage of the curable resin, or a crack appears in the curable sheet after the curable sheet is cured. Thus, the shape of the penetration hole is not stabilized, and this makes it difficult to accurately form the penetration hole.

The present invention [10] includes an inductor including: a magnetic sheet having a penetration hole, the penetration hole being open toward one side and the other side in a thickness direction and being along the thickness direction, the magnetic sheet extending in a direction perpendicular to the thickness direction, the magnetic sheet containing a cured resin and magnetic particles; and a conductive portion filled in the penetration hole and along the thickness direction of the magnetic sheet.

In this inductor, the magnetic sheet extends in the plane direction perpendicular to the thickness direction. The inductor can have a high inductance and sufficient superimposed DC current characteristics.

On the other hand, the magnetic layer described in Patent Document 1 is disposed only on the side surface of the conductive portion inside the penetration hole, and thus a high inductance and sufficient superimposed DC current characteristics cannot be achieved.

The inductor of the present invention can have a high inductance and sufficient superimposed DC current characteristics as compared with the inductor described in Patent Document 1.

The present invention [11] includes the inductor described in the above-described [10], further including: an insulating layer disposed between an inner peripheral surface facing the penetration hole in the magnetic sheet and an outer peripheral surface of the conductive portion.

The inductor further includes the insulating layer disposed between the inner peripheral surface of the magnetic sheet and the outer peripheral surface of the conductive portion. Thus, the conductive portion can surely be insulated from the magnetic sheet.

The present invention [12] includes the inductor described in the above-described [11] wherein the conductive portion includes: an underlying layer disposed on an inner surface of the insulating layer and at least at one side of the magnetic sheet in the thickness direction; and a main body disposed inside the underlying layer.

In this inductor, the underlying layer is allowed to function as a connecting pad.

### Effects of the Invention

According to the method of producing an inductor of the present invention, an inductor with a high inductance can be produced, and the conductive portion can easily be formed while the degree of freedom of the disposition of the conductive portion is increased.

The inductor of the present invention has a high inductance and sufficient superimposed DC current characteristics.

### BRIEF DESCRIPTION OF THE DRAWINGS

FIG. 1A is a plan view of one embodiment of the inductor of the present invention. FIG. 1B is a cross-sectional view taken along line X-X of FIG. 1A.

FIG. 2A shows a step of forming a curable sheet. FIG. 2B shows a step of curing the curable sheet. FIG. 2C shows a step of forming a penetration hole. FIG. 21) shows a step of forming an insulating layer.

FIG. 3E shows a step of forming an underlying layer. FIG. 3F shows a step of disposing a conductive paste in the penetration hole. FIG. 3G is a step of calcining the conductive paste. FIG. 3H is a step of removing an unnecessary part of the underlying layer.

### DESCRIPTION OF THE EMBODIMENT

### 1. One Embodiment of Inductor

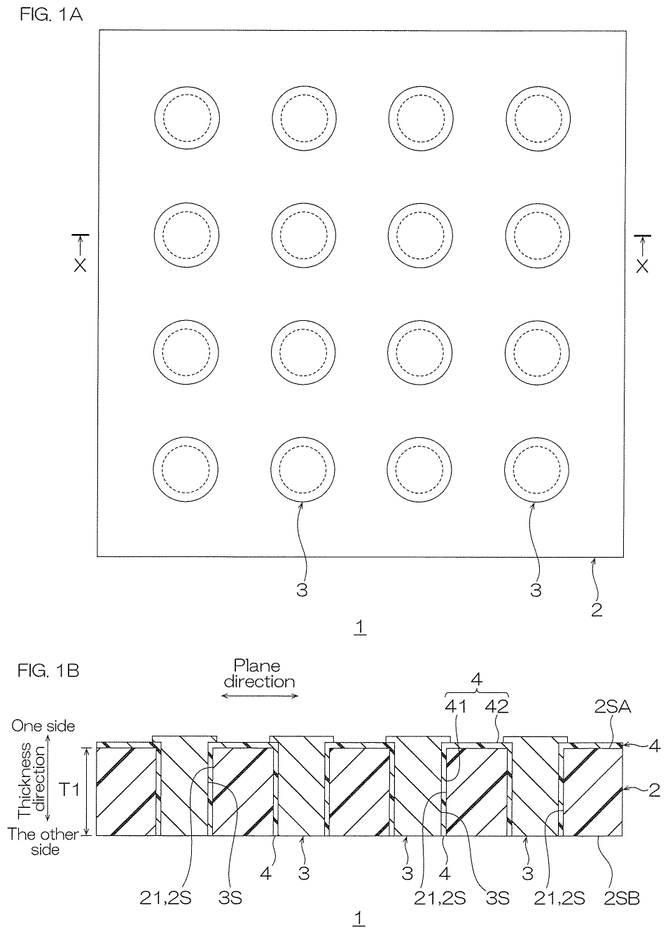

With reference to FIG. 1A and FIG. 1B one embodiment of an inductor of the present invention is described.

An inductor 1 has a thickness. The inductor 1 has the shape of a sheet. The inductor 1 is along a plane direction. The plane direction is perpendicular to the thickness. The inductor 1 includes a magnetic sheet 2, a conductive portion 3, and an insulating layer 4 (see FIG. 1B).

### 1.1 Magnetic Sheet 2

The magnetic sheet 2 extends in the plane direction (an example of a direction perpendicular to a thickness direction). The magnetic sheet 2 has one surface 2SA and the other surface 2SB facing each other in the thickness direction. The magnetic sheet 2 further has a penetration hole 21.

### 1.1.1 Penetration Hole 21

The penetration hole 21 is along the thickness direction. The penetration hole 21 is open toward one side and the other side in the thickness direction. In the present embodiment, the penetration hole 21 has an approximately circular shape when viewed in the thickness direction. In the present embodiment, a plurality of penetration holes 21 is arrayed at intervals therebetween in the plane direction.

The magnetic sheet 2 has an inner peripheral surface 2S facing the above-described penetration hole 21.

### 1.1.2 Material of Magnetic Sheet 2

The magnetic sheet 2 contains a resin component and magnetic particles.

The resin component is a resin matrix that disperses the magnetic particles in the magnetic sheet 2. The resin component contains at least a cured resin. The cured resin is a cured product (cured body) of a curable resin. Examples of the curable resin include thermosetting resin and photo-curable resin. Preferably, a thermosetting resin composition is used. The curable resin is prepared, for example, as a resin composition. The resin composition contains, for example, a main agent, a curing agent, and a curing accelerator. The resin composition is described, for example, in Japanese Unexamined Patent Publication No. 2020-150057, Japanese Unexamined Patent Publication No. 2020-150063, and Japanese Unexamined Patent Publication No. 2020-150066. The ratio of the cured resin in the magnetic sheet 2 is, for example, 5 vol % or more, preferably 10 vol % or more, and, for example, 60 vol % or less, preferably 50 vol % or less.

Examples of the magnetic particles include soft magnetic particles. The soft magnetic particles are described, for example, in Japanese Unexamined Patent Publication No. 2020-150057 Japanese Unexamined Patent Publication No. 2020-150063, and Japanese Unexamined Patent Publication No. 2020-150066. In the present embodiment, the magnetic particles do not include hard magnetic particles. The hard magnetic particles include ferrite. When including hard magnetic particles, the magnetic particles become a core having a high holding force and are not suitable for the present invention. The ratio of the magnetic particles with respect to 100 parts by mass of the cured resin is, for example, 400 parts by mass or more, preferably 500 parts by mass or more, and, for example, 4000 parts by mass or less, preferably 3500 parts by mass or less. The ratio of the magnetic particles in the magnetic sheet 2 is, for example, 25 vol % or more, preferably 30 vol % or more, and, for example, 75 vol % or less, preferably 70 vol % or less.

### 1.1.3 Dimensions of Magnetic Sheet 2

The magnetic sheet 2 has a thickness T1 of, for example, 1 μm or more, preferably 2 μm or more, and, for example, 20 mm or less, preferably 10 mm or less. The thickness T1 of the magnetic sheet 2 corresponds to the length of the penetration hole 21 in the thickness direction.

When viewed in the thickness direction, the penetration hole 21 has a maximum length of, for example, 1 μm or more, preferably 10 μm or more, and, for example, 100 mm or less, preferably 50 mm or less. When the penetration hole 21 has an approximately circular shape, the above-described maximum length corresponds to the diameter of the penetration hole 21. An interval between the penetration holes 21 adjacent to each other is, for example, 1 μm or more, preferably 2 μm or more, and, for example, 100 mm or less, preferably 50 mm or less.

### 1.2 Conductive Portion 3

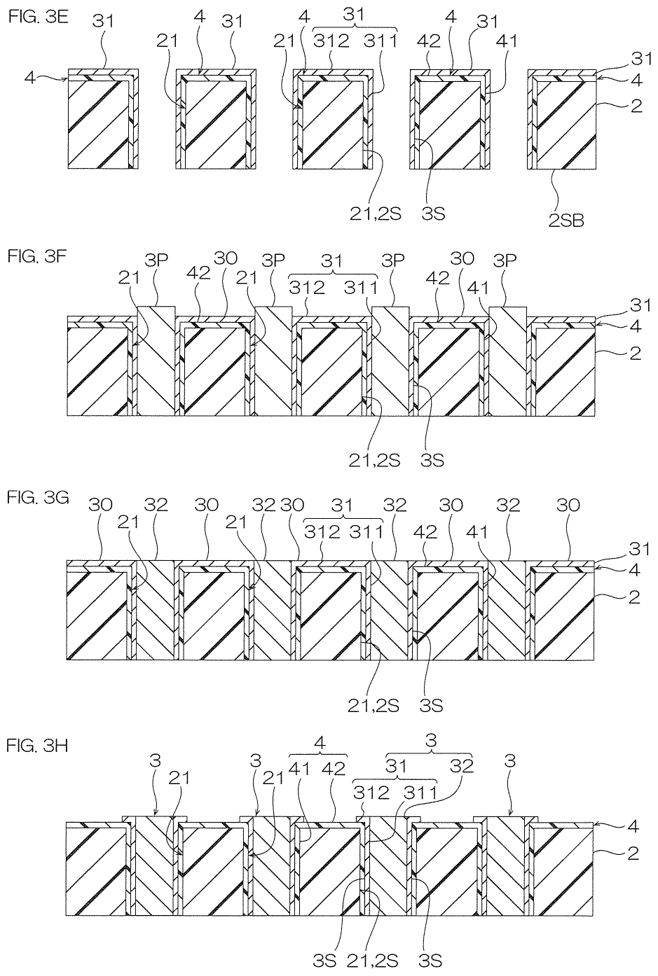

The conductive portion 3 mainly has a part filled in the penetration hole 21. The conductive portion 3 is along the thickness direction of the magnetic sheet 2. The conductive portion 3 has an approximately T shape in the cross-sectional view. In the present embodiment, the conductive portion 3 is provided corresponding to each of a plurality of penetration holes 21. As shown in FIG. 3H, each of the conductive portions 3 includes an underlying layer 31 and a main body 32.

### 1.2.1 Underlying Layer 31

The underlying layer 31 is disposed inside the penetration hole 21 and also at one side of the magnetic sheet 2. The underlying layer 31 functions as an underlying layer of the main body 32. The underlying layer 31 has an approximately hat shape in the cross-sectional view along the thickness direction. The underlying layer 31 has a first portion 311 and a second portion 312.

The first portion 311 is disposed inside the penetration hole 21. In the present embodiment, the first portion 311 has an approximately tubular shape. The first portion 311 is along the thickness direction. The first portion 311 forms an outer peripheral surface 3S of the conductive portion 3.

The second portion 312 is located at one end portion of the underlying layer 31 in the thickness direction. The second portion 312 is continuous to the first portion 311. The second portion 312 extends from one end edge of the first portion 311 in the thickness direction to the outside. In the present embodiment, the second portion 312 has an approximately circular shape in the thickness direction.

The second portion 312 corresponds to the brim of the hat. The second portion 312 can form a connecting pad together with one surface of the first portion 311 in the thickness direction.

### 1.2.2 Main Body 32

The main body 32 is filled in the first portion 311. The main body 32 is in contact with an inner peripheral surface of the first portion 311 of the underlying layer 31. The main body 32 is a main portion of the conductive portion 3. The main body 32 is along the thickness direction of the magnetic sheet 2. In the present embodiment, the main body 32 has a column shape. The axis of the cylinder is along the thickness direction.

### 1.2.3 Material of Conductive Portion 3

Examples of the material of the conductive portion 3 include a conductive material. Examples of the conductive material include gold, silver, copper, and an alloy. The materials of the underlying layer 31 and the main body 32 may be different or the same.

### 1.2.4 Dimensions of Conductive Portion 3

The underlying layer 31 has a thickness of, for example, 5 nm or more, preferably 10 nm or more, and, for example, 100 μm or less, preferably 50 μm or less. The thickness of the underlying layer 31 is the thickness of each of the first portion 311 and the second portion 312. The thickness of the first portion 311 is the thickness in a radial direction. The thickness of the second portion 312 is a length in the thickness direction.

The main body 32 has a length in the thickness direction of, for example, 1 μm or more, preferably 2 μm or more, and, for example, 20 mm or less, preferably 10 mm or less.

When viewed in the thickness direction, the main body 32 has a maximum length of, for example, 1 μm or more, preferably 10 μm or more, and, for example, 100 mm or less, preferably 50 mm or less.

When the main body 321 has a column shape, the main body 32 has a maximum length corresponding to the diameter of the main body 32.

The ratio of the thickness of the underlying layer 31 with respect to the above-described maximum length of the main body 32 is, for example, 1 or less, preferably 0.1 or less, and, for example, 5×10⁻⁸ or more, preferably 1×10⁻⁷ or more.

As shown in FIG. 3H, in the conductive portion 3, a boundary between the underlying layer 31 and the main body 32 may clearly be observed. Alternatively, as shown in FIG. 1B, in the conductive portion 3, the above-described boundary, the underlying layer 31, and the main body 32 may not clearly be observed.

### 1.3 Insulating Layer 4

The insulating layer 4 has a function of insulating the conductive portion 3 from the magnetic sheet 2. The insulating layer 4 is provided corresponding to each of a plurality of penetration holes 21 and each of a plurality of conductive portions 3. Each of a plurality of insulating layers 4 has a third portion 41 and a fourth portion 42.

The third portion 41 is disposed between the inner peripheral surface 2S of the magnetic sheet 2 and the outer peripheral surface 3S of the conductive portion 3 (first portion 311). In the present embodiment, the third portion 41 has an approximately cylindrical tubular shape. The axis of the cylindrical tube is along the thickness direction.

The fourth portion 42 is disposed on one surface of the magnetic sheet 2 in the thickness direction and one surface of the third portion 41 in the thickness direction. The fourth portion 42 extends in the plane direction.

Examples of the material of the insulating layer 4 include an insulating resin and an insulating inorganic material. Examples of the insulating resin include epoxy, acryl, polyester, polyurethane, polyesterimide, polyamideimide, and polyimide. Examples of the insulating inorganic material include silica, alumina, zirconia, titanium oxide, magnesium oxide, tin oxide, tantalum oxide, and silicon nitride.

The insulating layer 4 has thickness of, for example, 0.01 μm or more, and, for example, 100 μm or less. The thickness of the insulating layer 4 includes the thickness of the third portion 41 and the thickness of the fourth portion 42.

### 1.4 Method of Producing Inductor 1

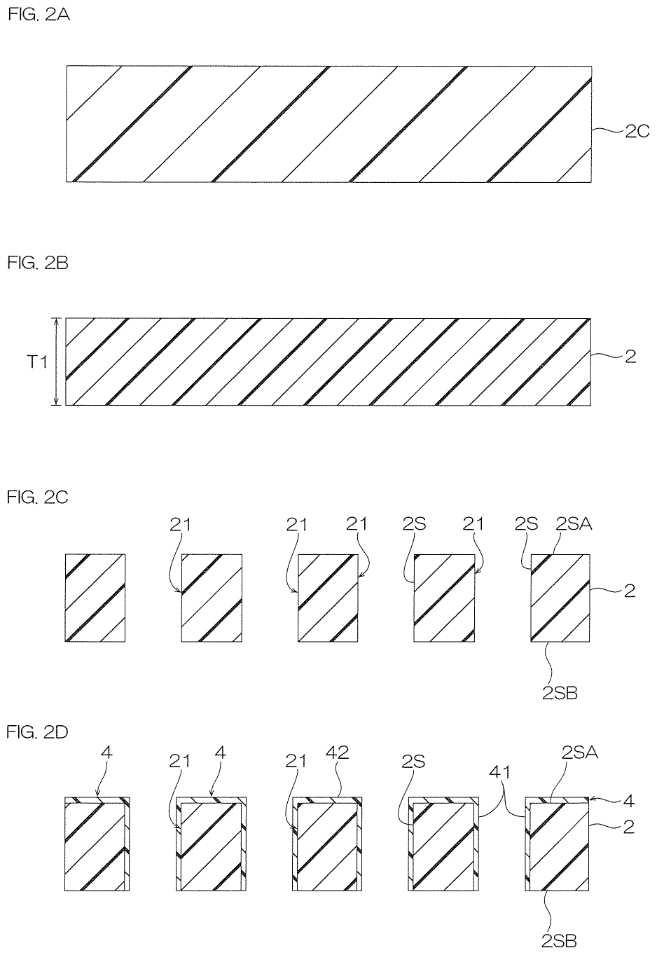

With reference to FIG. 2A to FIG. 3H, a method of producing the inductor 1 is described.

This production method includes a step of forming a magnetic sheet 2, a step of forming a penetration hole 21 in the magnetic sheet 2, a step of forming an insulating layer 4 on the magnetic sheet 2, and a step of forming the conductive portion 3 in the penetration hole 21.

### 1.4.1 Step of Forming Magnetic Sheet 2

In the step of forming a magnetic sheet 2, as shown in FIG. 2A, a curable sheet 2C is first formed.

The curable sheet 2C contains a resin component and magnetic particles. The resin component contains a curable resin and a thermoplastic resin. The curable resin contains an epoxy resin and a, phenol resin. The thermoplastic resin contains an acrylic resin. In other words, the resin component contains an epoxy resin, a phenol resin, and an acrylic resin.

The epoxy resin is an epoxy resin having 3 or more functional groups in its molecule (a multifunctional epoxy resin). Examples of the functional groups include a, glycidyl group.

Specifically, examples of the multifunctional epoxy resin include a phenol novolak epoxy resin, a cresol novolak epoxy resin, a trishydroxyphenylmethane epoxy resin, and a tetraphenylethane epoxy resin. As the multifunctional epoxy resin, preferably, a cresol novolak epoxy resin is used.

The epoxy resin preferably only consists of an epoxy resin having 3 or more functional groups. In other words, the epoxy resin in the resin component does not substantially contain an epoxy resin having 2 functional groups.

The phenol resin is a curing agent for the epoxy resin. The phenol resin is a phenol resin having 3 or more functional groups at its molecule (a multifunctional phenol resin). As the functional group, preferably, a hydroxyl group is used.

Examples of the multifunctional phenol resin include a phenol novolak resin, a cresol novolak resin, a phenol aralkyl resin, a phenol biphenylene resin, a dicyclopentadiene phenol resin, and a resol resin. As the multifunctional phenol resin, preferably, a phenol biphenylene resin is used.

The phenol resin preferably consists of a phenol resin having 3 or more functional groups. In other words, the phenol resin in the resin component does not substantially contain a phenol resin having 2 functional groups.

The phrase “does not substantially contain a phenol resin having 2 functional groups” means that the content ratio of the phenol resin having 2 functional groups in the whole phenol resin is, for example, 1.0% by weight or less, preferably 0.5% by mass or less, more preferably 0% by mass.

Examples of the acrylic resin include an acrylic polymer produced by preparing t type or 2 types or more of alkyl(meth)acrylate having a straight-chain or branched alkyl group as a monomer component, and polymerizing the monomer component. The term “(meth)acryl” represents “acryl and/or methacryl.”

Examples of the alkyl group include an alkyl group having 1 to 20 carbon atom(s). Examples of the alkyl group having 1 to 20 carbon atom(s) include methyl, ethyl, propyl, isopropyl, n-butyl, t-butyl, isobutyl, amyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl. As the alkyl group, preferably, an alkyl group having 1 to 6 carbon atom(s) is used.

The acrylic polymer may be a copolymer of an alkyl(meth)acrylate and another monomer.

Examples of the other monomer include a glycidyl group-containing monomer, a carboxyl group-containing monomer, an acid anhydride monomer, a hydroxyl group-containing monomer, a sulfonic acid group-containing monomer, a phosphoric acid group-containing monomer, a styrene monomer, and an acrylonitrile. Examples of the glycidyl group-containing monomer include a glycidyl acrylate and a glycidyl methacrylate. Examples of the carboxyl group-containing monomer include acrylic acid, methacrylic acid, carboxy ethyl acrylate, carboxy pentyl acrylate, itaconic acid, maleic acid, fumaric acid, and crotonic acid. Examples of the acid anhydride monomer include maleic anhydride and itaconic acid anhydride. Examples of the hydroxyl group-containing monomer include 2-hydroxyethyl (meth)acrylate, 2-hydroxypropyl (meth)acryl late, 4-hydroxy butyl (meth)acrylate, 6-hydroxyhexyl(meth)acylate, 8-hydroxyoctyl(meth)acrylate, 10-hydroxydecyl(meth)acrylate, 12-hydroxy lauryl (meth)acrylate, and (4-hydroxymethylcyclohexyl)methyl acrylate. Examples of the sulfonic acid group-containing monomer include styrenesulfonic acid, allylsulfonic acid, 2-(meth)acrylamide-2-methylpropanesulfonic acid, (meth)acrylamide propanesulfonic acid, sulfopropyl(meth)acrylate, and (meth)acryloyl oxy naphthalenesulfonic acid. Examples of the phosphoric acid group-containing monomer include 2-hydroxyethyl acryloyl phosphate. These can be used alone or in combination of two or more.

The acrylic resin preferably has at least one group of a carboxy group and a hydroxyl group. More preferably, the acrylic resin has both of the carboxy group and the hydroxyl group. In this manner, an occurrence of a gap is more surely suppressed, and the magnetic property can be improved.

The content ratio of the acrylic resin in the resin component is 25 vol % or more, preferably 30 vol % or more, more preferably 35 vol % or more, and, for example, 80 vol % or less, preferably 70 vol % or less, more preferably 60 vol % or less. When the content ratio of the acrylic resin is in the above-described range, a high processability can be imparted to the magnetic sheet 2 at the formation of the penetration hole 21. Furthermore, when the content ratio of the acrylic resin is in the above-described range, springback of the magnetic sheet 2 can be suppressed. Furthermore, the filling property of the magnetic particles and/or the orientation of the magnetic particles in the magnetic sheet 2 can be improved. As a result, the magnetic property of the magnetic sheet 2 can be improved.

The resin component can further contain a curing accelerator. Examples of the curing accelerator include an imidazole compound.

Then, to form a curable sheet 2C, as shown with the phantom line of FIG. 2A, a varnish is applied to form a coating film. The varnish contains a resin composition, magnetic particles, and a solvent. An example of the formulation of the resin composition is shown in Table 1 below.

TABLE 1

| Formulations of resin composition | | | vol % |
|---|---|---|---|
| Thermoplastic | Carboxyl group-containing | TEISANRESIN SG-70LN manufactured | 48.7 |
| component | acrylate polymer | by Nagase ChemteX Corporation | |
| Thermosetting | Cresol novolak epoxy | EPICLON N-665-EXP-S | 25.3 |
| component | resin (Main agent) | manufactured by DIC | |
| (Epoxy resin | Phenol resin | MEHC-7851SS manufactured by | 25.3 |
| composition) | (Curing agent) | MEIWA PLASTIC INDUSTRIES, LTD. | |
| | Imidazole compound | 2PHZ-PW manufactured by SHIKOKU | 0.7 |
| | (Curing accelerator) | KASEI HOLDINGS CORPORATION | |

Next, the coating film is dried. In the drying as necessary, the coating film is heated. By the drying, the solvent is removed from the coating film. In this manner, a curable sheet 2C is formed.

The curable sheet 2C is a sheet before being completely cured, specifically, is a B stage sheet or an A stage sheet. The A stage is a state in which the curable resin is in a liquid state. The B stage is a state in which the curable resin is between the above-described A stage and a C stage in which the curable resin is completely cured. Specifically, the B stage is a state in which the curing of the curable resin slightly progresses and the compressive elastic modulus is smaller than that of the C stage.

As shown in FIG. 2B, thereafter, the curable sheet 2C is cured. When the curable resin is a thermosetting resin, the curable sheet 2C is heated. When the curable resin is a photo-curable resin, the curable sheet 2C is irradiated with light. In this manner, the curable resin is completely cured (into the C stage). In this manner, a magnetic sheet 2 containing a cured product (cured body) of the curable resin is formed.

The magnetic sheet 2 does not have a penetration hole 21 yet.

### 1.4.2 Step of Forming in Magnetic Sheet 2

Next, in this step, as shown in FIG. 2C, a penetration hole 21 is formed. In other words, after the step of curing the magnetic sheet 2 (see FIG. 2B), the step of forming a penetration hole 21 (see FIG. 2C) is carried out. In this step, the magnetic sheet 2 is processed by at least one selected from the group consisting of drilling, blasting, and dicing. In addition to the above, examples of processing the magnetic sheet 2 include dry etching. Preferably, at least one selected from the group consisting of drilling, blasting, and dicing is used. The above-described one can easily form a penetration hole 21 at an arbitrary position in the magnetic sheet 2, and is advantageous as compared with dry etching.

### 1.4.3 Step of Forming Insulating Layer 4 on Magnetic Sheet 2

Next, as shown in FIG. 21D an insulating layer 4 is formed on an inner peripheral surface 2S and one surface 2SA of the magnetic sheet 2. For example, the insulating layer 4 is formed by photolithography. Specifically, a release film (not shown) is disposed on the other surface of the magnetic sheet 2. Next, a photosensitive insulating resin composition is disposed on one surface of the release film and on the inner peripheral surface 2S and the one surface 2SA of the magnetic sheet 2. Thereafter, the third portion 41 and the fourth portion 42 are formed by photolithography.

### 1.4.4 Step of Forming Conductive Portion 3 in Penetration Hole 21

Next, shown in FIG. 3E to FIG. 3H, a conductive portion 3 is formed in the penetration hole 21. The step of forming the conductive portion 3 includes a step of forming an underlying layer 31 (see FIG. 3E), a step of forming a main body 32 (see FIG. 3G), and a step of removing an unnecessary part 30 of the underlying layer 31 (see FIG. 3H).

As shown in FIG. 3F, in the step of forming an underlying layer 31, the underlying layer 31 is formed on an inner peripheral surface of the insulating layer 4 and on one surface of the insulating layer 4 in the thickness direction. Specifically, a first portion 311 is formed on an inner peripheral surface of the third portion 41 of the insulating layer 4, and the second portion 312 is formed on one surface of the fourth portion 42 in the thickness direction. In the step of forming the underlying layer 31, sputtering or plating is used. Examples of plating include non-electrolytic plating. In this manner, the first portion 311 and the second portion 312 are simultaneously formed.

As shown in FIG. 3F, the second portion 312, which is formed in this step, is formed on all the one surfaces of the fourth portions 42 of the insulating layer 4. At that time, the second portion 312 includes an unnecessary part 30. The unnecessary part 30 is a part except the second portion 312 when viewed in the thickness direction, and a part that is not included in the underlying layer 31 of the inductor 1 as a product (see FIG. 3H).

As shown in FIG. 3F and FIG. 3G, to form a main body 32, after the step of forming an underlying layer 31, a conductive paste 3P is filled inside the underlying layer 31 (see FIG. 3F), thereafter, the conductive paste 3P is calcined (see FIG. 3G). The conductive paste 3P is disposed on the inner peripheral surface of the first portion 311 of the underlying layer 31. On the other hand, the conductive paste 3P is not disposed on one surface of the second portion 312 in the thickness direction. In the present embodiment, one surface of the conductive paste 3P in the thickness direction is disposed separate from the one surface of the second portion 312 toward one side in the thickness direction. In other words, the one surface of the conductive paste 3P is raised toward one side in the thickness direction relative to the one surface of the second portion 312.

Examples of the conductive paste include the above-described conductive materials and organic materials. Examples of the shape of the conductive material include a particulate form. The organic material is a component that is decomposed and removed by calcination described next, and a component that does not substantially remain in the conductive portion 3.

As shown in FIG. 3G, thereafter, the conductive paste 3P is calcined. The conditions for the calcination are not limited. By the calcination of the conductive paste 3P, a main body 32 is formed. In the present embodiment, the one surface of the main body 32 is flush with the one surface of the second portion 312.

Thereafter, as shown in FIG. 3H, in the step of removing an unnecessary part 30 of the underlying layer 31, for example, etching is used. By the removal of the unnecessary part 30, the second portion 312 of the underlying layer 31 is formed. In other words, the underlying layer 31 consisting of the first portion 311 and the second portion 312 is formed.

In this manner, a conductive portion 3 having the underlying layer 31 and the main body 32 is formed.

### 2. Operations and Effects of One Embodiment

According to the method of producing the inductor 1 of the present embodiment, as shown in FIG. 2C, the penetration hole 21 is formed in the magnetic sheet 2, thereafter, as shown in FIG. 3H, the conductive portion 3 can be formed in the penetration hole 21. Thus, the conductive portion 3 can be easily formed while the degree of freedom of the disposition of the conductive portion 3 is increased.

Furthermore, the magnetic sheet 2 extends in the plane direction, and thus the inductance of the inductor 1 can be increased and the superimposed DC current characteristics are also improved.

According to the method of producing the inductor 1 of the present embodiment, the magnetic sheet 2 is processed by at least one selected from the group consisting of drilling, blasting, and dicing in the step of forming the penetration hole 21. Thus, the penetration hole 21 is easily formed at an arbitrary position in the magnetic sheet 2.

According to the method of producing the inductor 1 of the present embodiment, the second portion 312 of the underlying layer 31 is formed on the one surface 2SA of the magnetic sheet 2 in the thickness direction. Thus, the second portion 312 is allowed to function as a connecting pad.

According to the method of producing the inductor 1 of the present embodiment, the conductive paste 3P is filled inside the first portion 311 of the underlying layer 31. Thus, the main body 32 of the underlying layer 31 can easily be formed.

According to the method of producing the inductor 1 of the present embodiment, when the resin component in the curable sheet 2C contains an epoxy resin, a phenol resin, and an acrylic resin, and the content ratio of the acrylic resin in the resin component is 25 vol % or more and 60 vol % or less, a high processability is imparted to the magnetic sheet 2 at the formation of the penetration hole 21.

In the inductor 1, while the conductive portion 3 is along the thickness direction, the magnetic sheet 2 extends in the plane direction. Thus, the inductance can be increased, and excellent superimposed DC current characteristics are achieved.

On the other hand, the magnetic layer described in Patent Document 1 is disposed only between the board and the conductive portion inside the penetration hole, and thus a high inductance and sufficient superimposed DC current characteristics cannot be achieved.

As compared with the inductor described in Patent Document 1, the inductor 1 of the present embodiment can have a high inductance and excellent superimposed DC current characteristics.

This inductor 1 further includes the insulating layer 4 disposed between the inner peripheral surface 2S of the magnetic sheet 2 and the outer peripheral surface 3S of the conductive portion 3. Thus, the conductive portion 3 can surely be insulated from the magnetic sheet 2.

This inductor 1 includes the underlying layer 31, and thus allows the underlying layer 31 to function as a connecting pad.

### 3. Variations

In each of the following variations, the same members and steps as in the above-described one embodiment are given the same reference numerals, and the detailed descriptions thereof are omitted. Further, unless specified otherwise, each of the variations can have the same operations and effects as one embodiment does. Furthermore, one embodiment and each variation can appropriately be combined.

Although not shown, the insulating layer 4 may be disposed on the other surface of the conductive portion 3 in the thickness direction.

Although not shown, the conductive portion 3 may include only a main body 32 without including an underlying layer 31.

Although not shown, the underlying layer 31 may be disposed on the other side of the magnetic sheet 2 in the thickness direction.

The step of forming a penetration hole may be carried out before the step of curing the magnetic sheet 2. In other words, a penetration hole 21 is formed in the curable sheet 2C, and thereafter the curable sheet 2C is cured.

When a penetration hole is formed in the curable sheet 2C before the curable sheet 2C is thermally cured as described in the above-described variation, the degree of difficulty of the process increases. For example, this makes it difficult to control the shape of the penetration hole in consideration of the thermal shrinkage of the curable resin, or a crack appears in the curable sheet 2C after the curable sheet 2C is cured. Thus, the shape of the penetration hole is not stabilized, and this makes it difficult to accurately form the penetration hole.

On the other hand, in the above-described one embodiment, the step of forming a penetration hole 21 (see FIG. 2C) is carried out after the step of curing the curable sheet 2C (see FIG. 2B). Thus, the excellent filling property of the magnetic particles is maintained, in other words, the excellent magnetic property is maintained, and the thermally-cured magnetic sheet 2 can stably be processed. Thus, while the penetration hole 21 is accurately formed, excellent processing stability of the above-described magnetic sheet 2 having the penetration hole 21 is achieved.

While the illustrative embodiments of the present invention are provided in the above description, such is for illustrative purpose only and it is not to be construed as limiting in any manner. Modification and variation of the present invention that will be obvious to those skilled in the art is to be covered by the following claims.

### INDUSTRIAL APPLICABILITY

The production method is used for the production of inductors.

### DESCRIPTION OF REFERENCE NUMERALS

1 inductor
2 magnetic sheet
2C curable sheet
2S inner peripheral surface
2SA one surface
3 conductive portion
3S outer peripheral surface
3P conductive paste
4 insulating layer
21 penetration hole
31 underlying layer
32 main body
100 cured resin
321 main body

1. A method of producing an inductor, the method comprising:
a step of curing a curable sheet containing a curable resin and magnetic particles to form a magnetic sheet extending in a direction perpendicular to a thickness direction;
a step of forming a penetration hole in the magnetic sheet so that the penetration hole is open toward one side and the other side of the magnetic sheet in the thickness direction and is along the thickness direction; and
a step of forming a conductive portion in the penetration hole so that the conductive portion is along the thickness direction of the magnetic sheet.

2. The method of producing an inductor according to claim 1, wherein in the step of forming a penetration hole, the magnetic sheet is processed by at least one selected from the group consisting of drilling, blasting, and dicing.

3. The method of producing an inductor according to claim 1, the method further comprising:
a step of forming an insulating layer on an inner peripheral surface facing the penetration hole in the magnetic sheet;
wherein in the step of forming a conductive portion, the conductive portion is disposed on an inner peripheral surface of the insulating layer.

4. The method of producing an inductor according to claim 3,
wherein the step of forming a conductive portion includes a step of forming an underlying layer on the inner peripheral surface of the insulating layer and on at least one surface of the magnetic sheet in the thickness direction.

5. The method of producing an inductor according to claim 4,
wherein the step of forming a conductive portion includes a step of filling a conductive paste inside the underlying layer and calcining the conductive paste to form a main body after the step of forming the underlying layer.

6. The method of producing an inductor according to claim 1,
wherein the curable sheet contains a resin component,
wherein the resin component contains: an epoxy resin and a phenol resin that are contained in the curable resin; and an acrylic resin, and
wherein a content ratio of the acrylic resin in the resin component is 25 vol % or more and 60 vol % or less.

7. The method of producing an inductor according to claim 6,
wherein the epoxy resin only consists of an epoxy resin having 3 or more functional groups, and
wherein the phenol resin only consists of a phenol resin having 3 or more functional groups.

8. The method of producing an inductor according to claim 7,
wherein the epoxy resin having 3 or more functional groups is a cresol novolak epoxy resin, and
wherein the phenol resin having 3 or more functional groups is a phenol biphenylene resin.

9. The method of producing an inductor according to claim 1,
wherein the step of forming a penetration hole is carried out after the step of curing a curable sheet.

10. An inductor comprising:
a magnetic sheet having a penetration hole, the penetration hole being open toward one side and the other side in a thickness direction and being along the thickness direction, the magnetic sheet extending in a direction perpendicular to the thickness direction, the magnetic sheet containing a cured resin and magnetic particles; and
a conductive portion filled in the penetration hole and along the thickness direction of the magnetic sheet.

11. The inductor according to claim 10, further comprising:
an insulating layer disposed between an inner peripheral surface facing the penetration hole in the magnetic sheet and an outer peripheral surface of the conductive portion.

12. The inductor according to claim 11,
wherein the conductive portion includes:
an underlying layer disposed on an inner surface of the insulating layer and at least at one side of the magnetic sheet in the thickness direction; and
a main body disposed inside the underlying layer.

13. The method of producing an inductor according to claim 2, the method further comprising:
a step of forming an insulating layer on an inner peripheral surface facing the penetration hole in the magnetic sheet;
wherein in the step of forming a conductive portion, the conductive portion is disposed on an inner peripheral surface of the insulating layer.

14. The method of producing an inductor according to claim 2,
wherein the curable sheet contains a resin component,
wherein the resin component contains: an epoxy resin and a phenol resin that are contained in the curable resin; and an acrylic resin, and
wherein a content ratio of the acrylic resin in the resin component is 25 vol % or more and 60 vol % or less.

15. The method of producing an inductor according to claim 2,
wherein the step of forming a penetration hole is carried out after the step of curing a curable sheet.
